(19) United States
(12) Patent Application Publication
(10) Pub. No.: US 2025/0257442 A1
(43) Pub. Date: Aug. 14, 2025

(54) METALLIC COATED GASKETS USEFUL FOR FRONT CONTACTS IN ELECTROLYSIS

(71) Applicant: Lawrence Livermore National Security, LLC, Livermore, CA (US)

(72) Inventors: Sarah E. Baker, Dublin, CA (US); Aditya Prajapati, Livermore, CA (US); Andrew Allen Wong, Oakland, CA (US); Christopher Hahn, Half Moon Bay, CA (US); Maxwell Ivan Goldman, Oakland, CA (US)

(21) Appl. No.: 18/440,657

(22) Filed: Feb. 13, 2024

(51) Int. Cl. C23C 14/20; C25B 3/26; C25B 11/032

(52) U.S. Cl. CPC C23C 14/20; C25B 3/26; C25B 11/032

(57) ABSTRACT

A product, in accordance with one aspect of the present invention, includes a gasket comprising: a resiliently deformable electrically insulative portion, and an electrically conductive layer formed directly on the electrically insulative portion. A method for creating a product, in accordance with one aspect of the present invention, includes forming an electrically conductive layer on a resiliently deformable electrically insulative portion of a gasket via physical vapor deposition.

This invention was made with Government support under Contract No. DE-AC52-07NA27344 awarded by the United States Department of Energy. The Government has certain rights in the invention.

### FIELD OF THE INVENTION

The present invention relates to gaskets, and more particularly, this invention relates to metallic coated gaskets that are particularly useful with electrolyzers and fuel cells, and methods of making the same.

### BACKGROUND

Electrolysis refers generally to techniques for using an electrical current to drive an otherwise non-spontaneous chemical reaction.

For CO₂ electrolysis, gas diffusion electrodes are typically formed on top of either a carbon support that is coated in polytetrafluoroethylene (PTFE), or an expanded PTFE support. For a carbon-based support, the gas diffusion electrode has through-plane conductivity, so a current collector and a flow field act as the electrical path for electrons between the power source and the catalyst surface.

Literature has shown that increasing the hydrophobicity of the gas diffusion layer by replacing the carbon support with expanded PTFE can increase CO₂ electrolysis performance. However, because expanded PTFE is electrically insulative, the electrons can no longer be supplied from behind the electrode, therefore requiring the use of a front contact. In the present state of the art, front contacts are either copper tape covered with Kapton or copper wires. However, both solutions generally lead to poor electrical conductivity and high contact resistance. Also because the conductivity of such solutions is in-plane, and depending on the in-plane conductivity of the electrode, multiple points of contact are typically required. The disadvantages of the prior art include high cell voltages due to high contact resistances that drastically increase the full cell potential compared to a carbon-based gas diffusion layer.

### SUMMARY

A product, in accordance with one aspect of the present invention, includes a gasket comprising: a resiliently deformable electrically insulative portion, and an electrically conductive layer formed directly on the electrically insulative portion.

A method for creating a product, in accordance with one aspect of the present invention, includes forming an electrically conductive layer on a resiliently deformable electrically insulative portion of a gasket via physical vapor deposition.

Other aspects and advantages of the present invention will become apparent from the following detailed description, which, when taken in conjunction with the drawings, illustrate by way of example the principles of the invention.

### BRIEF DESCRIPTION OF THE DRAWINGS

FIG. 1 is a perspective view of a gasket, in accordance with one aspect of the present invention.

FIG. 2 is an exploded view of an electrolyzer for CO₂ electrolysis, in accordance with one aspect of the present invention.

FIG. 3 is a side view depicting a catalyst layer overlying the electrically conductive layer of the gasket along the entire aperture thereof.

FIG. 4 is a side view depicting a catalyst layer overlying the electrically conductive layer of the gasket along two sides of the aperture thereof.

FIG. 5 is a partial cross sectional view of an electrolyzer with the gasket compressed, in accordance with one aspect of the present invention.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

For the purposes of this application, room temperature is defined as in a range of about 20° C. to about 25° C.

As also used herein, the term “about” denotes an interval of accuracy that ensures the technical effect of the feature in question. In various approaches, the term “about” when combined with a value, refers to plus and minus 10% of the reference value. For example, a thickness of about 10 nm refers to a thickness of 10 nm±1 nm, a temperature of about 50° C. refers to a temperature of 50° C.±5° C., etc.

It is also noted that, as used in the specification and the appended claims, wt. % is defined as the percentage of weight of a particular component is to the total weight/mass of the mixture. Vol. % is defined as the percentage of volume of a particular compound to the total volume of the mixture or compound. Mol. % is defined as the percentage of moles of a particular component to the total moles of the mixture or compound. Atomic % (at. %) is defined as a percentage of one type of atom relative to the total number of atoms of a compound.

Unless expressly defined otherwise herein, each component listed in a particular approach may be present in an effective amount. An effective amount of a component means that enough of the component is present to result in a discernable change in a target characteristic of a mixture, an ink, a printed structure, and/or final product in which the component is present, and preferably results in a change of the characteristic to within a desired range. One skilled in the art, now armed with the teachings herein, would be able to readily determine an effective amount of a particular component without having to resort to undue experimentation.

The following description discloses various products including electrically conductive gaskets, such as gaskets to be used in an electrolyzer that requires a front contact to allow for electrical conductivity, the electrolyzer itself, etc. Methods of manufacture are also presented.

In one general approach, a product includes a gasket comprising: a resiliently deformable electrically insulative portion, and an electrically conductive layer formed directly on the electrically insulative portion.

In another general approach, a method for creating a product includes forming an electrically conductive layer on a resiliently deformable electrically insulative portion of a gasket via physical vapor deposition.

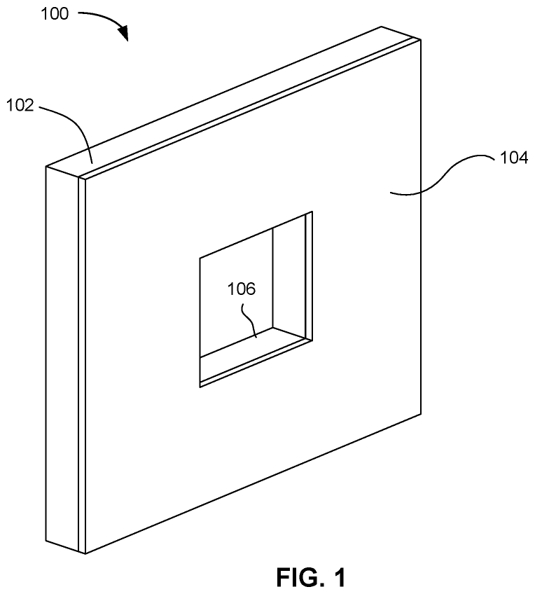

FIG. 1 depicts a gasket 100, not to scale, in accordance with one approach. As an option, the present gasket 100 may be implemented in conjunction with features from any other aspect of the present invention listed herein, such as those described with reference to the other FIGS. Of course, however, such gasket 100 and others presented herein may be used in various applications and/or in permutations which may or may not be specifically described in the illustrative approaches listed herein. Further, the gasket 100 presented herein may be used in any desired environment.

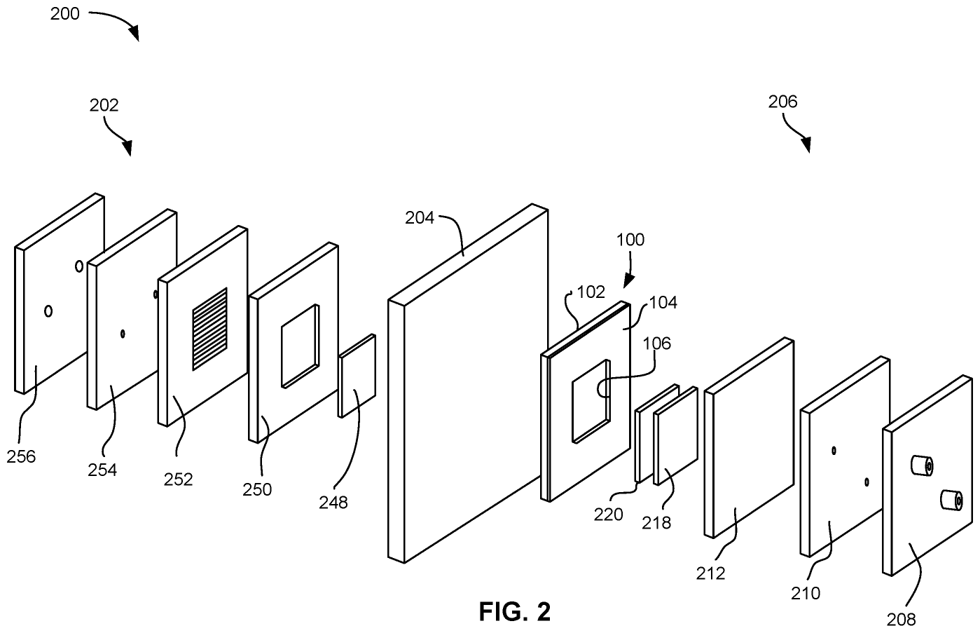

The gasket 100 includes an electrically insulative portion 102 and an electrically conductive layer 104 formed directly on the electrically insulative portion 102. The electrically insulative portion 102 of the gasket 100 is preferably resiliently deformable, e.g., able to deform upon being squeezed between two surfaces and return at least in part to its previous shape upon removal of the squeezing, to enhance the ability of the gasket to form a seal with adjacent components. An aperture 106 extends through the gasket 100. Further details of the gasket 100, in accordance with various approaches, are provided below in the description of FIG. 2.

As noted above, conventional CO₂ electrolysis uses either a carbon-based support for the gas diffusion electrode, or electrically-insulating expanded PTFE for said support. While expanded PTFE provides increased electrolysis performance, it also then requires use of a front contact with in-plane conduction. However, disadvantages of prior attempts to provide the front contact include high cell voltages due to high contact resistances that drastically increase the full cell potential compared to a carbon-based gas diffusion layer.

Various aspects of the present invention overcome the current limitations by having some, and preferably all, sides of the gas diffusion electrode in direct contact with the conductive electrically conductive layer of the gasket noted above, that is in turn in contact with the flow field. The increased contact area, coupled with reasonable compression (e.g., up to about 80 PSI), allows various inventive systems described herein to reach cell voltages that are about the same as if a carbon-based gas diffusion layer had been used.

FIG. 2 depicts an electrolyzer 200 for CO₂ electrolysis, not to scale, in accordance with one approach. As an option, the present electrolyzer 200 may be implemented in conjunction with features from any other aspects listed herein, such as those described with reference to the other FIGS. Of course, however, such electrolyzer 200 and others presented herein may be used in various applications and/or in permutations which may or may not be specifically described in the illustrative approaches listed herein. Further, the electrolyzer 200 presented herein may be used in any desired environment.

All parts of the electrolyzer 200 may be of conventional construction, except for the gasket 100, which has the new and novel construction disclosed herein.

As shown, the electrolyzer 200 includes an anode housing and feed section 202, an anion exchange membrane (AEM) 204, and a cathode housing and feed section 206. The cathode housing and feed section 206, in this example, includes a connector portion 208 for receiving a feed fluid, e.g., CO₂ and H₂O if the electrolyzer 200 is to be used as a CO₂ electrolyzer; a current collector 210; a flow field 212; and a gasket 100 that acts as a sealing component. The gasket 100 includes an aperture 106 adjacent the flow channel of the flow field 212.

The current collector 210 and flow field 212 are electrically conductive. The flow field 212 may be formed of graphite or some other conventional material. Likewise, the current collector 210 may be of conventional construction.

With continued reference to FIG. 2, a gas diffusion layer 218 is positioned between the gasket 100 and the flow field 212. A catalyst layer 220 is positioned on/adjacent a side of the gas diffusion layer 218 facing away from the flow field 212. The catalyst layer 220 may be discrete layer, or may be formed on the gas diffusion layer 218 using conventional deposition techniques. As described in detail below, the gasket 100 provides an electrically conductive pathway between the flow field 212 and the catalyst layer 220.

The gasket 100 includes an electrically insulative portion 102 and an electrically conductive layer 104 formed directly on the electrically insulative portion 102. The electrically insulative portion 102 of the gasket 100 is preferably resiliently deformable, at least in part, to enhance its ability to form a seal with adjacent components.

The electrically insulative portion 102 should be formed of a material that is essentially inert when in contact with the fluids being operated on by the electrolyzer 200. Any suitable electrically insulative material that is inert to the reactants that would become apparent to one skilled in the art after reading the present disclosure may be used. In preferred approaches, the electrically insulative portion 102 is formed from PTFE, or a reinforced PTFE for use with higher temperatures, due to the desirably hydrophobicity of the PTFE and its appurtenant benefits. Other illustrative materials from which the electrically insulative portion 102 may be formed include neoprene, natural rubber, synthetic rubber, Kapton, PTFE coated fiberglass, insulating tape, perfluoropolyether (PFPE), silicon, ethylene propylene diene monomer (EPDM) rubber, etc. Laminates of any of the foregoing materials may also be used. Preferably, the electrically insulative portion 102 is formed of a material that is inert to the fluids being used in the electrolyzer. For CO₂ electrolyzers, a hydrophobic electrically insulative portion 102 may be preferable. For H₂O electrolyzers, a hydrophilic electrically insulative portion 102 may be preferable.

The electrically insulative portion 102 of the gasket 100 may be formed via any suitable process, such as injection molding, blow molding, casting, additive manufacturing, cutting from a larger sheet of material, etc.

The electrically conductive layer 104 is formed directly on the electrically insulative portion 102 of the gasket 100, and faces the flow field 212. The electrically conductive layer 104 may be formed of any suitable conductive material that would become apparent to one skilled in the art after reading the present disclosure. Illustrative materials include, but are not limited to metals such as copper, silver, gold, bismuth (e.g., ¹⁰Bi), any metal that is a catalyst for the target fluid (e.g., a CO₂ catalyst), alloys of metals, platinum, palladium, titanium, a transition metal (preferably an inert transition metal), alloys of such metals, laminated layers of such metals, etc. For CO₂ electrolyzers, a copper catalyst is particularly useful for electrolyzing CO₂ to ethylene, while gold and silver catalysts are particularly useful for electrolyzing CO₂ to CO.

In preferred approaches, the catalyst layer 220 and the electrically conductive layer 104 comprise the same metal, and in some approaches, the catalyst layer 220 and the electrically conductive layer 104 both consist essentially of (or consist of) the same metallic material. Note that where a metal of the electrically conductive layer 104 is different than the metal of the catalyst layer 220, the metal of the electrically conductive layer 104 is preferably essentially inert, at least to the fluids being processed. Exemplary essentially inert metals include platinum, palladium, and titanium.

In further approaches, the electrically conductive layer 104 may be carbonaceous, e.g., formed of carbon such as graphene, formed of an electrically conductive carbon derivative, etc.

The deposition thickness of the electrically conductive layer 104 is preferably selected so as to provide at least a desired level of electrical conductivity from the flow field 212 to the catalyst layer 220 (described below). An illustrative deposition thickness of the electrically conductive layer 104 is in a range of about 1 nm to about 5 microns. Preferably, the thickness of the electrically conductive layer 104 is below 2 microns to avoid delamination, ensure uniformity of thickness, ensure good sealing, etc. Preferred thicknesses for the electrically conductive layer 104 are in a range of about 10 nm to about 2 microns. In some approaches, the thickness of the electrically conductive layer 104 is in a range of about 50 nm to about 1 micron, in other approaches about 75 nm to about 500 nm, in other approaches about 100 nm to about 400 nm, in other approaches about 200 nm to about 1 micron, in other approaches about 500 nm to about 2 microns, etc.

The electrically conductive layer 104 preferably extends to the perimeter of the gasket 100 to maximize contact with the flow field 212, e.g., the electrically conductive layer 104 covers an entire face of the electrically insulative layer 102. However, the electrically conductive layer 104 may have smaller dimensions than the perimeter of the gasket 100 in some approaches.

The electrically conductive layer 104 is preferably formed on the electrically insulative portion 102 via physical vapor deposition (PVD). This fabrication technique enables formation of a uniformly thick conductive layer 104 with good adhesion, which is important for creating a good seal, yet that is thin enough to deform with the electrically insulative portion 102, which is also important for creating a good seal. Examples of PVD techniques include, but are not limited to, sputter deposition, electron beam deposition, etc. Accordingly, the electrically conductive layer 104 has physical characteristics of formation on the electrically insulative portion 102 by PVD. Such physical characteristics include a substantially uniform deposition thickness, shadowing effects at the edges of the formed layer, an atomic lattice structure characteristic of formation by PVD, and other characteristics that would become apparent to one skilled in the art after reading the present disclosure.

Note that good adhesion occurs between the electrically conductive layer 104 and the electrically insulative portion 102 without any special cleaning of the electrically insulative portion 102, though conventional cleaning techniques may be used, e.g., conventional RCA-1 cleaning to remove organics, conventional RCA-2 cleaning to remove heavy metals, etc.

In one approach, the gas diffusion layer 218 comprises porous carbon, and is thus electrically conductive. In this case, electricity can flow from the flow field 212, through the gas diffusion layer 218, to the catalyst layer 220.

In preferred approaches, the gas diffusion layer 218 is electrically insulating. For example, for CO₂ electrolysis, a hydrophobic gas diffusion layer 218 is beneficial, and thus the gas diffusion layer 218 may be formed of a hydrophobic material such as porous PTFE or expanded PTFE. PTFE and expanded PTFE are electrically insulative, and therefore the gas diffusion layer 218 electrically isolates the catalyst layer 220 from the flow field 212. However, when the electrolyzer 200 is assembled, the electrically conductive layer 104 of the gasket 100 abuts the flow field 212 (or intervening layer) and thus provides a path of conductivity from the flow field 212 to the catalyst layer 220.

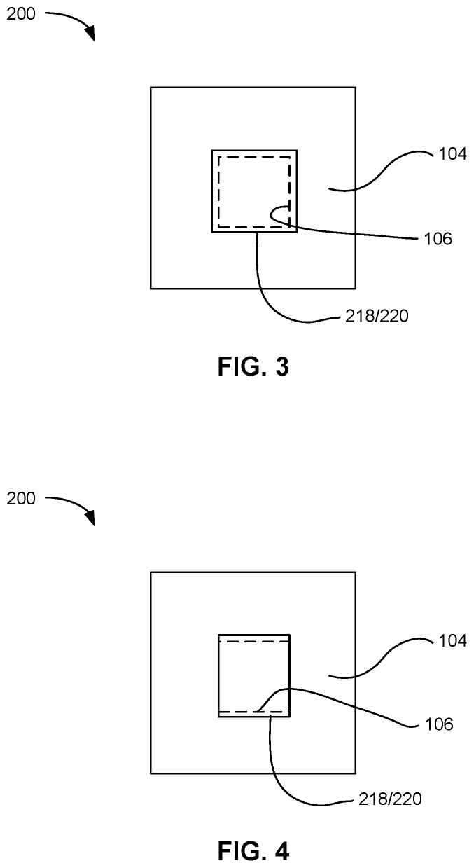

To facilitate electrical coupling between the catalyst layer 220 and the electrically conductive layer 104, the gas diffusion layer 218 (and catalyst layer 220) may be slightly larger than the aperture 106 in at least one dimension so that the gas diffusion layer 218 and catalyst layer 220 overlie the electrically conductive layer 104 slightly along at least one edge of the catalyst layer 220, preferably along several edges, and ideally have overlap along all edges of the catalyst layer 220 to thereby form a full ring of electrical contact between an annular perimeter of the catalyst layer 220 that overlies the electrically conductive layer 104 along the aperture 106. FIG. 3 depicts an approach in which the catalyst layer 220 overlies the electrically conductive layer 104 along the entire aperture 106. FIG. 4 depicts an approach in which the catalyst layer 220 overlies the electrically conductive layer 104 along two sides of the aperture 106.

Once the gasket 100 is compressed during assembly of the electrolyzer 200, the result is good electrical contact between the flow field 212 and electrically conductive layer 104, as well as between the electrically conductive layer 104 and the catalyst layer 220 due do the overlap therebetween, consequently resulting in excellent the electrical connectivity between the current collector 210, flow field 212 and the catalyst layer 220.

The sealing provided by the gasket 100 is sufficient for any reasonable use of the electrolyzer 200. In one approach, the gasket 100 provides sealing up to at least 130 PSI, and in some approaches sealing is provided up to at least 140 PSI.

A great benefit of using the gasket 100 with PTFE electrically insulative portion 102 and electrically conductive layer 104 as described herein is that the resulting CO₂ electrolyzer 200 exhibits similar cell voltages as if the gas diffusion layer 218 were constructed of copper.

The AEM 204 resides on an opposite side of the gasket 100 than the flow field 212. The AEM 204 may be of conventional construction, e.g., a polymeric membrane.

The anode housing and feed section 202 resides adjacent the AEM 204. The components of the anode housing and feed section 202 may be conventional. Illustrative components shown in FIG. 2 are a porous transport layer 248, gasket 250, flow field 252, current collector 254, and connector portion 256.

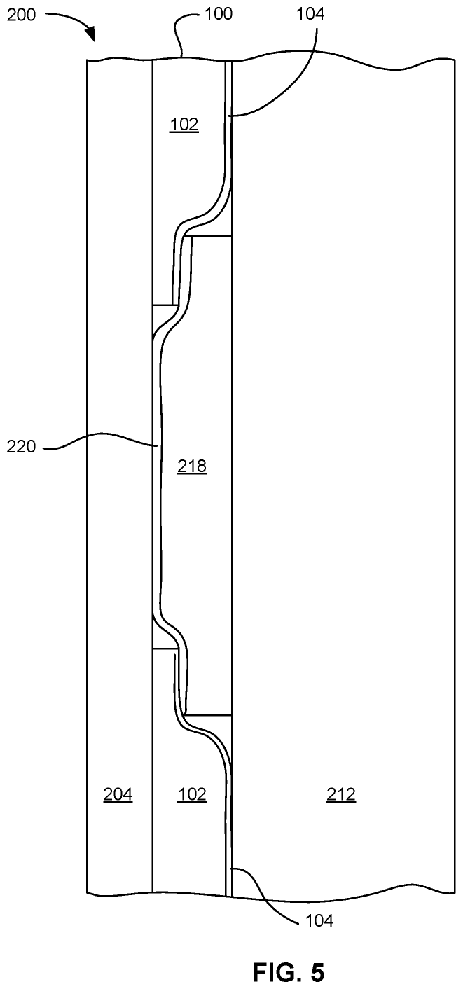

FIG. 5 depicts a partial cross sectional view of the electrolyzer 200, not to scale, with the gasket 100 compressed. As shown, the gas diffusion layer 218 with catalyst layer 220 thereon overlaps the gasket 100 adjacent the aperture 106 of the gasket. The overlap may be selected to provide adequate electrical contact between the catalyst layer 220 and the electrically conductive layer 104. The flow field 212 also contacts the electrically conductive layer 104, whereby the electrically conductive layer 104 provides an electrical conduit between the flow field 212 and the catalyst layer 220.

As shown, the catalyst layer 220 contacts the electrically conductive layer 104 on at least the top and bottom ends thereof. Again, various approaches may have contact only along one side of the catalyst layer 220, two sides thereof, three sides thereof, all sides thereof (e.g., annular), etc.

As shown, the gasket 100 may deform upon assembly of the electrolyzer to accommodate the overlapping portions of the gas diffusion layer 218 with catalyst layer 220 thereon, while engaging the flow field 212 to provide a good seal with the flow field, thereby enabling pressurization within the system, e.g., above atmospheric pressure.

Note that while the electrolyzer 200 of FIG. 2 depicts one exemplary approach, electrolyzers according to other aspects of the present invention may have any other configuration used in conventional electrolyzers, so long as the new and novel gasket disclosed herein is used. Accordingly, electrolyzers having other configurations while including the new and novel gasket disclosed herein are deemed to fall within the metes and bounds of the present invention. Such other configuration may include more or less components than those shown in FIG. 2, as would be appreciated by those skilled in the art after reading the present disclosure.

Illustrative types of electrolyzers include alkaline electrolyzers, proton exchange membrane (PEM) electrolyzers, solid oxide electrolyzers, zero gap electrolyzer, etc. For example, alkaline electrolyzers include a microporous separator, electrodes, and an aqueous alkaline electrolyte. The most common cathode material is nickel, with a catalytic coating such as platinum. PEM electrolyzers generally include a proton exchange membrane that uses a solid polymer electrolyte. Solid oxide electrolyzers, also known as solid oxide electrolysis cells (SOECs), use a solid oxide ceramic electrolyte.

A zero gap electrolyzer is a type of electrolyzer that has no gap between the anodes, cathodes, and electrolyte. The layers are pressed or bonded together, which reduces the distance for ion transport. Zero-gap electrolyzers are similar to fuel cells in design due to the two electrodes being pressed against a membrane. Zero-gap CO₂ electrolyzers can achieve high current densities (e.g., ≥100 mA/cm²) by delivering gaseous CO₂ to the cathode. The efficiency of these electrolyzers depends upon the catalysts used, the operating conditions, and the membrane chosen.

Likewise, the novel gasket described herein may be used with fuel cells of otherwise conventional construction.

Moreover, some approaches of the gasket may have an electrically conductive layer formed on opposite sides of the electrically insulative material. The electrically conductive layers may or may not be in electrical contact with one another.

The inventors have proceeded contrary to conventional wisdom on two fronts. This is especially so when the gasket is used in an electrolyzer. First, conventional wisdom is to use solely an inert material to act as a gasket for sealing. The metal of the electrically conductive layer in some approaches is not inert, e.g., copper. In some approaches, spots may be created on the electrode that are not electrochemically active but to are electrically active, Second, conventional wisdom would never have used a gas diffusion layer that extends onto the gasket in the belief that it would prevent sealing and ruin the cell compression. However, experimentation has shown that a good seal cab be achieved using a gasket created according the teachings presented herein.

### In Use:

Exemplary uses of the gaskets presented herein include use as an electrical contact between a catalyst surface for CO₂ reduction and a power source or potentiostat, e.g., of an electrolyzer or fuel cell. The new and novel gaskets described herein may be used in any other application that would become apparent to one skilled in the art after reading the present disclosure.

While various aspects of an inventive concept have been described above, it should be understood that they have been presented by way of example only, and not limitation. Thus, the breadth and scope of an aspect of an inventive concept of the present invention should not be limited by any of the above-described exemplary aspects of an inventive concept but should be defined only in accordance with the following claims and their equivalents.

What is claimed is:

1. A product, comprising:
a gasket comprising: a resiliently deformable electrically insulative portion, and an electrically conductive layer formed directly on the electrically insulative portion.

2. The product as recited in claim 1, wherein the electrically conductive layer has physical characteristics of formation on the electrically insulative portion by physical vapor deposition.

3. The product as recited in claim 1, wherein the electrically insulative portion comprises polytetrafluoroethylene.

4. The product as recited in claim 3, wherein the electrically conductive layer comprises a material selected from the group consisting of copper, gold, silver, and bismuth.

5. The product as recited in claim 1, wherein the electrically insulative portion is hydrophilic.

6. The product as recited in claim 1, wherein the electrically insulative portion is hydrophobic.

7. The product as recited in claim 1, wherein the electrically conductive layer comprises a metal.

8. The product as recited in claim 7, wherein the metal is selected from the group consisting of copper, gold, silver, and bismuth.

9. The product as recited in claim 1, wherein the gasket has an aperture therethrough.

10. The product as recited in claim 9, comprising a flow field facing the electrically conductive layer of the gasket, a gas diffusion layer between the gasket and the flow field and adjacent the aperture, and a catalyst layer between the gas diffusion layer and the gasket, wherein the catalyst layer overlies a portion of the electrically conductive layer along the aperture.

11. The product as recited in claim 10, wherein an annular perimeter of the catalyst layer overlies the portion of the electrically conductive layer along the aperture.

12. The product as recited in claim 10, wherein the product is an electrolyzer.

13. The product as recited in claim 12, wherein the electrolyzer is a CO₂ electrolyzer, wherein the electrically insulative portion comprises polytetrafluoroethylene, and wherein the electrically conductive layer comprises a metal selected from the group consisting of copper, silver, and gold.

14. The product as recited in claim 10, wherein the catalyst layer and the electrically conductive layer comprise a same metal.

15. The product as recited in claim 1, wherein the electrically conductive layer is carbonaceous.

16. A method for creating a product, the method comprising:
forming an electrically conductive layer on a resiliently deformable electrically insulative portion of a gasket via physical vapor deposition.

17. The method as recited in claim 16, wherein the electrically insulative portion is formed of polytetrafluoroethylene.

18. The method as recited in claim 17, wherein the electrically conductive layer comprises a material selected from the group consisting of copper, gold, silver, and bismuth.

19. The method as recited in claim 16, comprising assembling an electrolyzer that includes the gasket, wherein the electrolyzer includes a flow field facing the electrically conductive layer of the gasket, a gas diffusion layer between the gasket and the flow field and adjacent an aperture of the gasket, and a catalyst layer between the gas diffusion layer and the gasket, wherein the catalyst layer overlies and is in direct contact with a portion of the electrically conductive layer along the aperture.

20. The method as recited in claim 19, wherein the electrolyzer is a CO₂ electrolyzer, wherein the electrically insulative portion comprises polytetrafluoroethylene, and wherein the electrically conductive layer comprises a metal selected from the group consisting of: a same metal as the catalyst layer and an inert metal.

21. The method as recited in claim 16, wherein the physical vapor deposition is selected from the group consisting of sputter deposition and electron beam deposition.
